(19) United States
(12) Patent Application Publication
(10) Pub. No.: US 2025/0012987 A1
(43) Pub. Date: Jan. 9, 2025

(54) OPTICAL MODULE

(71) Applicant: HISENSE BROADBAND MULTIMEDIA TECHNOLOGIES CO., LTD., Qingdao (CN)

(72) Inventors: Xiaokuo ZHANG, Qingdao (CN); Xujie HUANG, Qingdao (CN); Jiaao ZHANG, Qingdao (CN); Xinnan WANG, Qingdao (CN); Jianwei MU, Qingdao (CN)

(21) Appl. No.: 18/889,577

(22) Filed: Sep. 19, 2024

Related U.S. Application Data
(63) Continuation of application No. PCT/CN2023/078703, filed on Feb. 28, 2023.

(30) Foreign Application Priority Data
Nov. 2, 2022 (CN) 202211364522.0
Nov. 2, 2022 (CN) 202211364526.9
Nov. 2, 2022 (CN) 202211364550.2
Nov. 2, 2022 (CN) 202222917149.9

(51) Int. Cl. G02B 6/42; G02B 6/43; H01S 5/02315; H01S 5/02345; H01S 5/0239

(52) U.S. Cl. CPC G02B 6/428; G02B 6/4246; G02B 6/4257; G02B 6/43; H01S 5/02315; H01S 5/02345; H01S 5/0239

(57) ABSTRACT

An optical module includes a circuit board, a first support member, a laser component and a detector component. The first support member supports the circuit board, a through hole is provided in the first support member below the circuit board; the laser component is provided on front surface of the first support member and electrically connected to welding pin on front surface of the circuit board through wire bonding; the detector component is provided on back surface of the circuit board, located in the through hole, and is electrically connected to signal wiring on back surface of the circuit board; the detector component is configured to convert reception light into electrical signal. With the first support member, light emission and reception components may be directly arranged on a carrier formed by the first support member and the circuit board, facilitating miniaturization of the optical module.

### CROSS-REFERENCE TO RELATED APPLICATIONS

This application is a continuation of PCT/CN2023/078703 filed on Feb. 28, 2023, which claims priority to Chinese Application No. 202211364522.0, filed on Nov. 2, 2022, Chinese Application No. 202211364526.9, filed on Nov. 2, 2022, Chinese Application No. 202222917149.9, filed on Nov. 2, 2022, and Chinese Application No. 202211364550.2, filed on Nov. 2, 2022, the disclosures of which are all incorporated herein by reference in their entireties.

### TECHNICAL FIELD

The present disclosure relates to the field of optical communication technology, and in particular, to an optical module.

### BACKGROUND

With the development of new services and application models such as cloud computing, mobile internet, and video, the development and progress of optical communication technology has become increasingly important. In the optical communication technology, an optical module is a tool for achieving interconversion between an optical signal and an electrical signal, and is one of the key components in optical communication equipment. In addition, with the development of optical communication technology, the transmission rate of the optical module is constantly increasing.

### SUMMARY

An optical module is provided according to some embodiments of this disclosure which includes an upper shell, a lower shell, a circuit board, a first support member, a laser component, a cover plate, a reflector and a detector component. The upper shell and the lower shell are combined to form a package cavity, and the circuit board, the first support member, the laser component, the cover plate, the reflector and the detector component are respectively arranged in the package cavity. A gold finger is arranged on a front surface of the circuit board at one end thereof, and a welding pin is arranged at the other end of the front surface of the circuit board. The gold finger is electrically connected to the welding pin through a signal line arranged on the front surface of the circuit board; and a signal wiring is arranged on a back surface of the circuit board. One end of the first support member supports and fixes the circuit board, and a through hole is provided in the first support member, and the through hole is located below the circuit board; the welding pin is located above the first support member, and the gold finger is located outside the first support member. The laser component is arranged on the front surface of the first support member, and is electrically connected to the welding pin through wire bonding; the laser component is configured to generate emission light. The cover plate is supported and connected to the back surface of the first support member and is embedded in the through hole of the first support member. The reflector is arranged on the cover plate and is configured to reflect a reception light to the detector component. The detector component is arranged on the back surface of the circuit board, is located in the through hole, and is electrically connected to the signal wiring on the back surface of the circuit board. The detector component is configured to convert the reception light into an electrical signal, and the electrical signal is transmitted through the signal wiring.

Some embodiments of the present disclosure also provide an optical module including a circuit board, a first support member, a laser component, a detector component, a second support member, a first optical fiber adapter and a second optical fiber adapter; a gold finger is provided at one end of the front surface of the circuit board, and a welding pin is provided at the other end of the front surface, and the gold finger is electrically connected to the welding pin through a signal line arranged on the front surface; a signal wiring is arranged on the back surface of the circuit board; the first support member, one end of which supports and fixes the circuit board, and a through hole is provided in the first support member, and the through hole is located below the circuit board; the welding pin is located on the first support member, and the gold finger is located outside the first support member; the laser component is provided on the front surface of the first support member, and is electrically connected to the welding pin through wire bonding; the laser component is configured to emit emission light; the detector component is provided on the back surface of the circuit board, located in the through hole, and is electrically connected to the signal wiring; the detector component is configured to perform photoelectric conversion on the reception light; one end of the second support member is connected to the other end of the first support member, the first optical fiber adapter is inserted in the other end of the second support member, is configured to emit signal light, and the second optical fiber adapter is inserted in the other end of the second support member and is configured to transmit the reception light.

### BRIEF DESCRIPTION OF THE DRAWINGS

The accompanying drawings to be used in some embodiments of the present disclosure will be described briefly below so as to more clearly describe the technical solutions of the present disclosure. The accompanying drawings described below are only those of some embodiments of the present disclosure, and for those skilled in the art, other drawings may also be derived from these accompanying drawings. In addition, the accompanying drawings as described below may be regarded as schematic diagrams and are not intended to limit the actual size of the product, the actual process of the method, or the actual timing of the signal involved in the disclosed embodiments.

FIG. 1 is a connection diagram of an optical communication system provided according to some embodiments of the present disclosure.

FIG. 2 is a structural diagram of an optical network terminal provided according to some embodiments of the present disclosure.

FIG. 3 is a structural diagram of an optical module provided according to some embodiments of the present disclosure.

FIG. 4 is a partial exploded view of an optical module provided according to some embodiments of the present disclosure.

FIG. 5 is a perspective diagram of a circuit board, a first support member and a light emission component in an optical module according to some embodiments of the present disclosure.

FIG. 6 is a perspective diagram of a circuit board, a first support member and a light reception component in an optical module according to some embodiments of the present disclosure.

FIG. 7 is a structural diagram of a first support member in an optical module according to some embodiments of the present disclosure.

FIG. 8 is a structural diagram of a first support member in an optical module provided in accordance with some embodiments of the present disclosure at another viewing angle.

FIG. 9 is a partial perspective view of a circuit board, a first support member and a light reception component in an optical module according to some embodiments of the present disclosure.

FIG. 10 is a partial perspective sectional view of a circuit board, a first support member and a light emission component in an optical module according to some embodiments of the present disclosure.

FIG. 11 is a partial perspective sectional view of a circuit board, a first support member and a light reception component in an optical module according to some embodiments of the present disclosure.

FIG. 12 is an exploded view of a circuit board, a first support member, a light reception component and a cover plate in an optical module according to some embodiments of the present disclosure.

FIG. 13 is a structural diagram of a cover plate in an optical module according to some embodiments of the present disclosure.

FIG. 14 is a partial perspective sectional view of a circuit board, a first support member, a light emission component and a light reception component in an optical module according to some embodiments of the present disclosure.

FIG. 15 is a structural diagram of a lower shell in an optical module according to some embodiments of the present disclosure.

FIG. 16 is a perspective view of a lower shell, a circuit board, a light emission component, a light reception component and a cover plate in an optical module according to some embodiments of the present disclosure.

FIG. 17 is a perspective view of a circuit board, a first support member, a second support member, a light emission component and an optical fiber adapter in an optical module according to some embodiments of the present disclosure.

FIG. 18 is a perspective view of a first support member and a second support member in an optical module according to some embodiments of the present disclosure.

FIG. 19 is an exploded view of a first support member and a second support member in an optical module according to some embodiments of the present disclosure.

FIG. 20 is a structural diagram of a second support member in an optical module according to some embodiments of the present disclosure.

FIG. 21 is a structural diagram of a second support member in an optical module provided in accordance with some embodiments of the present disclosure at another viewing angle.

FIG. 22 illustrates an emission optical path of an optical module provided according to some embodiments of the present disclosure.

FIG. 23 is a sectional view of an emission optical path of an optical module provided according to some embodiments of the present disclosure.

FIG. 24 is a sectional view of a second support member in an optical module according to some embodiments of the present disclosure.

FIG. 25 is a perspective view of a circuit board, a first support member, a second support member, a light reception component and an optical fiber adapter in an optical module according to some embodiments of the present disclosure.

FIG. 26 illustrates a reception optical path of an optical module provided according to some embodiments of the present disclosure.

FIG. 27 is a sectional view of a reception optical path of an optical module provided according to some embodiments of the present disclosure.

### DETAILED DESCRIPTION

Technical solutions of some embodiments of this disclosure will be described clearly and in detail with reference to the accompanying drawings below. Obviously, these embodiments are merely some, but not all, of the embodiments of this disclosure. All other embodiments obtained by those skilled in the art based on the embodiments of this disclosure fall within the protection scope of this disclosure.

The term “comprise” and other forms thereof such as the third-person singular form “comprises” and the present participle form “comprising” should be construed as open and inclusive, i.e., “including, but not limited to,” throughout the description and the claims unless the context indicates otherwise. In the description, terms such as “one embodiment,” “some embodiments,” “exemplary embodiments,” “example,” “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, features defined as “first” and “second” may explicitly or implicitly include one or more of the features. In the description of the embodiments of the present disclosure, the term “a plurality of” means two or more.

In the description of some embodiments, the terms “coupled” and “connected” and their extensions may be used. For example, the term “connected” may be used in the description of some embodiments to indicate that two or more components are in direct or indirect physical or electrical contact with each other. For another example, the term “coupled” may be used in the description of some embodiments to indicate that two or more components are in direct or indirect physical or electrical contact. However, the term “coupled” or “communicatively coupled” may also mean that two or more components are not in direct contact with each other, but still cooperate or interact with each other. The embodiments disclosed herein are not necessarily limited to the contents herein.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The use of the phrase “applicable to” or “configured to” herein means an open and inclusive language, which does not exclude devices that are applicable to or configured to perform additional tasks or steps.

The term “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

As used herein, “parallel”, “perpendicular”, and “equal” include the described situations and situations similar to the described situations, and the range of the similar situations is within the acceptable range of deviation, wherein the acceptable range of deviation is determined by a person of ordinary skill in the art taking into account the measurement being discussed and the errors associated with the measurement of a particular quantity (i.e., the limitations of the measurement system). For example, “parallel” includes absolute parallelism and approximate parallelism, wherein the acceptable range of deviation of approximate parallelism can be, for example, a deviation within 5°; “perpendicular” includes absolute perpendicularity and approximate perpendicularity, wherein the acceptable deviation range of approximate perpendicularity can also be, for example, a deviation within 5°; “equal” includes absolute equality and approximate equality, wherein the acceptable deviation range of approximate equality can be, for example, the difference between the two equalities is less than or equal to 5% of either one.

In optical communication technology, an optical signal is used to carry information to be transmitted, and the optical signal carrying the information is transmitted to an information processing device such as a computer through an information transmission device (medium) such as an optical fiber or an optical waveguide to complete transmission of the information. Since the light has a characteristic of passive transmission when being transmitted through the optical fiber or the optical waveguide, long-distance, low-cost and low-loss information transmission may be achieved. In addition, a signal transmitted by the information transmission device such as the optical fiber or the optical waveguide is an optical signal, while a signal that can be recognized and processed by the information processing device such as the computer is an electrical signal. Therefore, in order to establish information connection between the information transmission device such as the optical fiber or the optical waveguide and the information processing device such as the computer, it is necessary to achieve interconversion between the electrical signal and the optical signal.

An optical module is provided to perform interconversion between the optical signal and the electrical signal in the field of optical communication technology. The optical module includes an optical port and an electrical port. Optical communication between the optical module and the information transmission device such as the optical fiber or the optical waveguide is achieved through the optical port. Electrical connection between the optical module and an optical network terminal (e.g., an optical modem) is achieved through the electrical port. The electrical connection is mainly to achieve power supply, transmission of an I2C signal, transmission of a data information and grounding. The optical network terminal transmits the electrical signal to the information processing device such as the computer through a network cable or wireless fidelity technology (Wi-Fi).

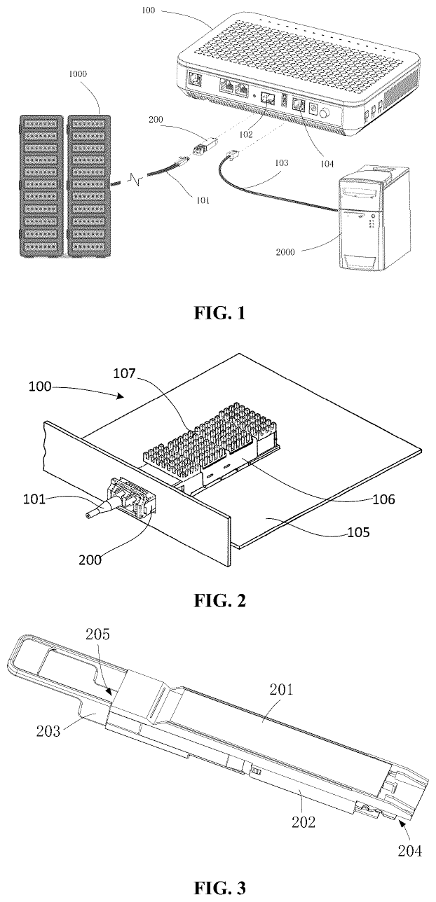

FIG. 1 is a diagram showing a connection relationship of an optical communication system provided according to some embodiments of the present application. As shown in FIG. 1, the optical communication system includes a remote server 1000, a local information processing device 2000, an optical network terminal 100, an optical module 200, an optical fiber 101 and a network cable 103.

One terminal of the optical fiber 101 is connected to the remote server 1000, and the other terminal of the optical fiber 101 is connected to the optical network terminal 100 through the optical module 200. The optical fiber itself may support long-distance signal transmission, such as several-kilometer signal transmission. Based on this, if a repeater is used, infinite-distance transmission may be achieved theoretically. Therefore, in a typical optical communication system, a distance between the remote server 1000 and the optical network terminal 100 may typically reach several kilometers, tens of kilometers, or hundreds of kilometers.

One terminal of the network cable 103 is connected to the local information processing device 2000, and the other terminal of the network cable 103 is connected to the optical network terminal 100. The local information processing device 2000 may be at least one of the followings: a router, a switch, a computer, a tablet computer, a television or the like.

A physical distance between the remote server 1000 and the optical network terminal 100 is greater than a physical distance between the local information processing device 2000 and the optical network terminal 100. Connection between the local information processing device 2000 and the remote server 1000 is completed by the optical fiber 101 and the network cable 103, and connection between the optical fiber 101 and the network cable 103 is completed by the optical module 200 and the optical network terminal 100.

The optical network terminal 100 includes a housing which is substantially in a cuboid shape, and an optical module interface 102 and a network cable interface 104 that are disposed on the housing. The optical module interface 102 is configured to access the optical module 200, such that a bidirectional electrical signal connection is established between the optical network terminal 100 and the optical module 200. The network cable interface 104 is configured to access the network cable 103, such that a bidirectional electrical signal connection is established between the optical network terminal 100 and the network cable 103. Connection between the optical module 200 and the network cable 103 is established through the optical network terminal 100. For example, the optical network terminal 100 transmits an electrical signal from the optical module 200 to the network cable 103, and transmits an electrical signal from the network cable 103 to the optical module 200. Therefore, the optical network terminal 100, as a master monitor of the optical module 200, may monitor operation of the optical module 200. In addition to the optical network terminal 100, the master monitor of the optical module 200 may further include an optical line terminal (OLT).

The optical module 200 includes the optical port and the electrical port. The optical port is configured to be connected with the optical fiber 101, such that a bidirectional optical signal connection is established between the optical module 200 and the optical fiber 101. The electrical port is configured to access the optical network terminal 100, such that a bidirectional electrical signal connection is established between the optical module 200 and the optical network terminal 100. Interconversion between the optical signal and the electrical signal is achieved by the optical module 200, such that connection between the optical fiber 101 and the optical network terminal 100 is established. For example, an optical signal from the optical fiber 101 is converted into an electrical signal by the optical module 200, and then the electrical signal is input into the optical network terminal 100; an electrical signal from the optical network terminal 100 is converted into an optical signal by the optical module 200, and then the optical signal is input into the optical fiber 101.

A bidirectional signal transmission channel is established between the remote server 1000 and the local information processing device 2000 through the optical fiber 101, the optical module 200, the optical network terminal 100, and the network cable 103.

FIG. 2 is a structural diagram of an optical network terminal provided according to some embodiments of this application. FIG. 2 only shows structures of the optical network terminal 100 that are related to the optical module 200 so as to clearly show a connection relationship between the optical module 200 and the optical network terminal 100. As shown in FIG. 2, the optical network terminal 100 includes a circuit board 105 disposed in the housing, a cage 106 disposed on a surface of the circuit board 105, a heat sink 107 disposed on the cage 106, and an electrical connector disposed inside the cage 106. The electrical connector is configured to access the electrical port of the optical module 200; the heat sink 107 has protruding structures such as fins for increasing a heat dissipation area.

The optical module 200 is inserted into the cage 106 of the optical network terminal 100, the optical module 200 is fixed by the cage 106, and heat generated by the optical module 200 is conducted to the cage 106 and is dissipated through the heat sink 107. After the optical module 200 is inserted into the cage 106, the electrical port of the optical module 200 is connected to the electrical connector in the cage 106, and thus the bidirectional electrical signal connection is established between the optical module 200 and the optical network terminal 100. In addition, the optical port of the optical module 200 is connected to the optical fiber 101, such that the bidirectional optical signal connection is established between the optical module 200 and the optical fiber 101.

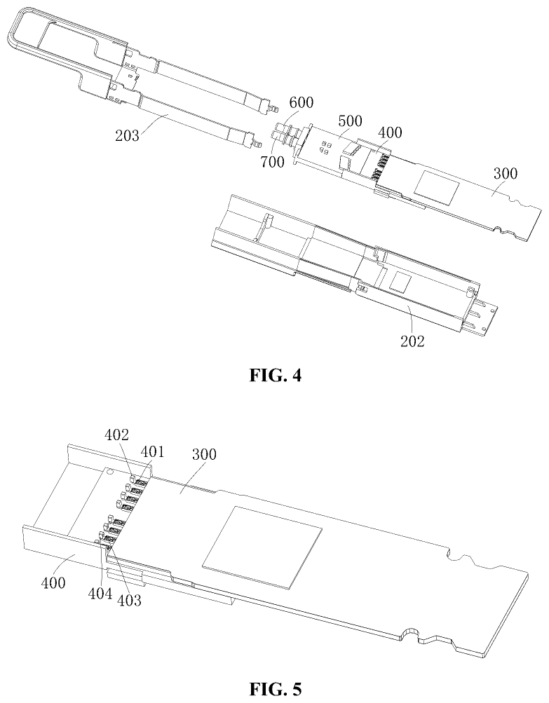

FIG. 3 is a structural diagram of an optical module provided in accordance with some embodiments of the present disclosure, and FIG. 4 is a partial exploded diagram of an optical module provided in accordance with some embodiments of the present disclosure. As shown in FIGS. 3 and 4, the optical module 200 includes a shell, a circuit board 300 disposed in the shell, a light emission component and/or a light reception component.

The shell includes a lower shell 202 and an upper shell 201 covers on the lower shell 202 to form the shell with two openings. An outer contour of the shell may be in a cuboid shape.

In some embodiments of this disclosure, the lower shell 202 includes a bottom plate and two lower side plates located on opposite sides of the bottom plate and disposed perpendicular to the bottom plate; the upper shell 201 includes a cover plate covers on the two lower side plates of the lower shell 202 to form the above mentioned shell.

In some embodiments, the lower shell 202 includes a bottom plate and two lower side plates located on both sides of the bottom plate and disposed perpendicular to the bottom plate; the upper shell 201 include a cover plate and two upper side plates located on both sides of the cover plate and disposed perpendicular to the cover plate, and the two upper side plates are combined with the two lower side plates, such that the upper shell 201 covers the lower shell 202.

By using an assembly mode of combining the upper shell 201 with the lower shell 202, it facilitates installation of the circuit board 30, the light emission component and/or the light reception component and other components into the shell, and the upper shell 201 and the lower shell 202 may form encapsulation and protection for these components. In addition, it facilitates to arrange positioning components, heat dissipation components, and electromagnetic shielding components of these devices when assembling the circuit board 30, the light emission component and/or the light reception component and other components, which is conducive to implementation of automated production.

In some embodiments, the upper shell 201 and the lower shell 202 are generally made of a metallic material, which facilitates electromagnetic shielding and heat dissipation.

A direction of a connecting line between the two openings 204 and 205 may be the same as a length direction of the optical module 200, or may not be the same as the length direction of the optical module 200. For example, the opening 204 is located at an end (a right end in FIG. 3) of the optical module 200, and the opening 205 is also located at an end (a left end in FIG. 3) of the optical module 200. Alternatively, the opening 204 is located at an end of the optical module 200, and the opening 205 is located at a side of the optical module 200. The opening 204 is the electrical port, and a gold finger of the circuit board 300 extends from the electrical port 204, and is inserted into the master monitor (e.g., the optical network terminal 100); the opening 205 is the optical port, which is configured to access the external optical fiber 101, such that the optical fiber 101 is connected to the light emission component and/or the light reception component in the optical module 200.

As shown in FIG. 3 and FIG. 4, in some embodiments, the optical module 200 further includes an unlocking component 203 located outside of the shell thereof, and the unlocking component 203 is configured to achieve or release a fixed connection between the optical module 200 and the master monitor.

For example, the unlocking component 203 is located on outer walls of the two lower side plates of the lower shell 202, and includes an engagement component that is matched with the cage of the master monitor (e.g., the cage 106 of the optical network terminal 100). When the optical module 200 is inserted into the cage of the master monitor, the optical module 200 is fixed in the cage of the master monitor via the engagement component of the unlocking component 203. When the unlocking component 203 is pulled, the engagement component of the unlocking component 203 moves therewith, which in turn changes a connection relationship between the engagement component and the master monitor to release engagement between the optical module 200 and the master monitor, such that the optical module 200 may be drawn out of the cage of the master monitor.

The circuit board 300 includes circuit wires, electronic elements, chips and the like. The electronic elements and the chips are connected together through the circuit wires according to a circuit design, so as to achieve functions of power supply, electrical signal transmission, grounding and the like. The electronic elements may include, for example, capacitors, resistors, triodes, and metal-oxide-semiconductor field-effect transistors (MOSFETs). The chips may include, for example, a microcontroller unit (MCU), a laser driver chip, a limiting amplifier (LA), a transimpedance amplifier (TIA), a clock and data recovery (CDR) chip, a power management chip, and a digital signal processing (DSP) chip.

The circuit board 300 is generally a rigid circuit board which may further achieve a load-bearing function due to its hard material. For example, the rigid circuit board may stably bear the above mentioned electronic elements and the chips. The rigid circuit board may also stably carry the light emission component and/or the light reception component when the light emission component and/or the light reception component are located on the circuit board. The rigid circuit board may also be inserted into the electrical connector in the cage of the master monitor.

The circuit board 300 also includes a gold finger formed on a surface of an end thereof. The gold finger is composed of a plurality of independent pins. The circuit board 300 is inserted into the cage 106 and is conductively connected to the electrical connector in the cage 106 through the gold finger. The gold finger may be disposed only on a surface of one side (e.g., the upper surface as shown in FIG. 4) of the circuit board 300, or be disposed on surfaces of both upper and lower sides of the circuit board 300 to adapt to occasions where a large number of pins are required. The gold finger is configured to establish electrical connection with the master monitor to achieve power supply, grounding, transmission of an I2C signal, transmission of a data signal, etc.

Of course, some optical modules also use flexible circuit boards. The flexible circuit board, as a supplement to the rigid circuit board, is generally used in conjunction with the rigid circuit board. For example, a flexible circuit board may be used to connect a rigid circuit board with a light emission component and a light reception component.

The light emission component and the light reception component may be packaged separately by a tubular shell, that is, the light emission component includes a tubular shell and a laser component (such as a laser chip), a lens, etc. located in the transmitting tubular shell. The light emission component may be electrically connected to the circuit board through a flexible circuit board to achieve signal transmission between the circuit board and the light emission component, to realize light emission.

The light reception component includes a tubular shell and a lens, a detector component (such as a detector chip), etc. located in the tubular shell. The light reception component may be electrically connected to the circuit board through a flexible circuit board to achieve signal transmission between the circuit board and the light reception component, and thus achieve light reception. In some examples, the detector chip may be called as a reception optoelectronic chip. In some embodiments, the packaging process of the light emission component and the light reception component includes TO-CAN (Transistor Outline-CAN) coaxial packaging, butterfly packaging, BOX packaging, and COB (Chip On Board) packaging. However, no matter which packaging manner is used, the laser chip, detector chip, lens and other optical processing elements are first assembled on a carrier, then connected to the circuit board, and finally assembled into the shell of the optical module. For example, when the light emission component and the light reception component adopt the BOX packaging method, there are many structural parts, the production process is complicated, and the invalid space in the optical module accounts for a high proportion, which is not conducive to the miniaturization and high-density integration of the optical module.

Laser chips are used to emit light used in fiber-optic communications (or optical fiber communications). Since laser chips and light transmission have high requirements on the temperature and humidity of the working environment, laser chips are generally packaged in independent packages in optical modules. For example, the coaxial package is used to package laser chips in access networks to form an airtight package to adapt to harsh outdoor environments.

With the change of optical module application scenarios and the increase of transmission rate, the use of laser chip arrays to increase transmission rate is mostly used in working environments such as data centers where temperature and humidity are stable and suitable. In this case, the requirement for data transmission rate is the first priority, and the unfavorable factors of the working environment have faded. Therefore, the optical modules provided according to some embodiments of the present disclosure use an open design for the laser chip and do not use independent packaging. In this regard, the optical module products have undergone a morphological innovation design with the development of technology and new requirements of application scenarios.

Some embodiments of the present disclosure provide an optical module, wherein a first support member is provided in a package cavity formed by an upper shell and a lower shell. The first support member is used as a carrier to realize the support of a circuit board, the support of a laser chip, the layout of optical elements, and the realization of emission and reception optical paths

The circuit board is located in the package cavity, and the circuit board is of a cuboid shape and has two ends along its length. A gold finger is provided at one end of the circuit board to realize electrical interaction between the circuit board and the host computer (or master monitor) through the gold finger. The other end of the circuit board is electrically connected to a laser component or a reception optoelectronic chip for realizing photoelectric conversion to realize the photoelectric conversion. In the present disclosure, in order to realize the electrical connection between the circuit board and the laser component or the reception optoelectronic chip, a welding pin is provided at the other end of the circuit board.

The gold fingers are located at the end edge of the circuit board, outside the package cavity formed by the upper and lower shells, and the gold fingers are interfaces for electrical connection between the optical module and the host computer. The gold fingers are configured to be inserted into the electrical connector of the host computer.

The welding pins are located at the end edge of the other end of the circuit board, arranged side by side in the width direction of the circuit board, occupying the width space of the circuit board. The welding pins are located inside the package cavity formed by the upper and lower shells, and are configured to electrically connect the laser components in the optical module. In some embodiments of the present disclosure, the welding pins can be divided into multiple groups, corresponding to multiple laser components, to form a laser component array.

An upper surface (front surface) of the circuit board is provided with high-speed transmission signal lines. In some embodiments of the present disclosure, the high-speed transmission signal lines are arranged in an array, that is, there are multiple groups of high-speed transmission signal lines, which are corresponded to multiple laser components. The high-speed transmission signal lines are connected to the welding pins to provide a transmission signal for the laser component.

In some embodiments of the present disclosure, a digital signal processing (DSP) chip is disposed on the upper surface of the circuit board. The digital signal processing chip is electrically connected to the high-speed transmission signal lines, and the digital signal processing chip provides the high-speed transmission signal.

There are a large number of laser components, such that the overall rate of the optical module can be cumulatively improved. The number of the welding pins corresponding to the laser components increases accordingly, occupying the width space on the upper surface of the circuit board, making it impossible to set the reception optoelectronic chip in the width space on the upper surface of the circuit board, resulting in the welding pins not connected to the high-speed reception signal line, that is, the light emission component and the light reception component cannot be arranged side by side in the width direction of the upper surface of the circuit board.

In some embodiments of the present disclosure, the reception optoelectronic chip is arranged on the lower surface (back surface) of the circuit board, and the high-speed transmission signal line corresponding to the laser component is arranged on the upper surface of the circuit board, that is, the light emission part and the light reception part are arranged on different surfaces of the circuit board. The high-speed reception signal line is arranged on the lower surface of the circuit board, and the reception optoelectronic chip is electrically connected to the high-speed reception signal line; the digital signal processing chip located on the upper surface of the circuit board is electrically connected to the high-speed reception signal line through the via hole in the circuit board, thereby realizing input of electrical signal generated by the reception optoelectronic chip into the digital signal processing chip.

In some embodiments of the present disclosure, the high-speed reception signal lines are arranged in an array, that is, there are multiple groups of high-speed reception signal lines, which are corresponded to multiple reception optoelectronic chips to form a reception optoelectronic chip array, that is, the detector component is a reception optoelectronic chip array.

The first support member is located inside the package cavity formed by the upper and lower shells. One end of the circuit board with a gold finger is arranged outside the first support member, and the other end of the circuit board with a welding pin is arranged on the first support member, and the lower surface of the circuit board faces the bottom surface of the first support member.

At this time, the reception optoelectronic chip is located in the gap between the lower surface of the circuit board and the bottom surface of the first support member, and this gap is very narrow, which is not convenient for installation. In some embodiments of the present disclosure, the bottom surface of the first support member is provided with a through hole at a position corresponding to the reception optoelectronic chip, and the reception optoelectronic chip is located at the through hole.

The welding pin is located at the edge of the end of the circuit board and is electrically connected to the laser component via a wire. That is, the laser component is electrically connected to the welding pin via wire bonding, and is configured to power the laser component. It is preferable that the wire of the electrical connection is as short as possible. In some embodiments of the present disclosure, the laser component is arranged on the bottom surface of the first support member at a position close to the edge of the circuit board.

A lens is arranged on the bottom surface of the first support member and is located in the optical path of the laser component to change the convergence degree of the light emitted by the laser component.

Side walls are arranged on both sides of the bottom surface of the first support member, the end of the circuit board abuts against the edges of the side walls, and the welding pins are located between the side walls.

FIG. 5 is a perspective diagram of a circuit board, a first support member, and a light emission component in an optical module according to some embodiments of the present disclosure, and FIG. 6 is a perspective diagram of a circuit board, a first support member, and a light reception component in an optical module according to some embodiments of the present disclosure. As shown in FIG. 5 and FIG. 6, the optical module includes a first support member 400, and one end of the first support member 400 is connected to the circuit board 300 to support and fix the circuit board 300. In some embodiments of the present disclosure, when the first support member 400 is connected to the circuit board 300, the circuit board 300 is arranged on the front surface at one end of the first support member 400, such that the back surface of the circuit board 300 is in contact and connected with the front surface of the first support member 400, so as to support and fix the circuit board 300 through the first support member 400.

The light emission component includes a laser component, which is directly arranged on the front surface of the first support member 400. The laser component is electrically connected to the circuit board 300 through wire bonding to generate signal light according to the electrical signal transmitted by the circuit board 300. The signal light is converged and transmitted through the optical devices on the front surface of the first support member 400.

In some embodiments, a gold finger is provided on the front surface of the circuit board 300 at one end thereof, and a welding pin is provided on the front surface of the circuit board 300 at the other end thereof. The gold finger is electrically connected to the welding pin through a signal line arranged on the front surface of the circuit board 300, so as to transmit the electrical signal received by the gold finger to the welding pin through the signal line, and then transmit it to the laser component through the wire bonding, to drive the laser component to generate emission light. It can be understood that the emission light is a signal light.

In some embodiments, a digital signal processing chip (DSP chip) may also be disposed on the front surface of the circuit board 300. One end of the DSP chip is electrically connected to the gold finger via a signal line, and the other end of the DSP chip is electrically connected to the welding pin via a signal line. In this way, the DSP chip provides an electrical signal to the laser component via the signal line and the welding pin to drive the laser component to generate emission light.

In some embodiments, the optical module further includes an optical fiber adapter, and the light emission component may be connected to the optical fiber adapter via an internal optical fiber to transmit the emission light generated by the light emission component to the optical fiber adapter via the internal optical fiber, and then transmit the emission light outside via the optical fiber adapter.

In some embodiments, the light emission component includes a first laser array 401, a first collimating lens array 402, a second laser array 403, and a second collimating lens array 404. The first laser array 401 and the second laser array 403 are arranged side by side on the front surface of the first support member 400, and are located close to a left side of the circuit board 300. Wire bonding heights of the first laser array 401 and the second laser array 403 are flush with the front surface of the circuit board 300. In this way, the first laser array 401 and the second laser array 403 are electrically connected to the welding pins on the circuit board 300 through bonding, such that the electrical signal transmitted through the circuit board 300 drives the first laser array 401 and the second laser array 403 to generate multiple paths of emission lights.

The first collimating lens array 402 and the second collimating lens array 404 are arranged side by side on the front surface of the first support member 400. The first collimating lens array 402 is located in A light exit direction of the first laser array 401 and is configured to convert the emission light generated by the first laser array 401 into collimated light. The second collimating lens array 404 is located in A light exit direction of the second laser array 403 and is configured to convert the emission light generated by the second laser array 403 into collimated light.

In some embodiments, the first laser array 401 includes four lasers, which are arranged side by side on the front surface of the first support member 400. Each laser generates one path of emission light, and thus the first laser array 401 generates four paths of emission light with different wavelengths. The first collimating lens array 402 includes four collimating lenses, and each collimating lens is located in the light exit direction of a corresponding laser.

The second laser array 403 includes four lasers, which are arranged side by side on the front surface of the first support member 400. Each laser generates one path of emission light, and thus the second laser array 403 generates four paths of emission light with different wavelengths. The second collimating lens array 404 includes four collimating lenses, each of which is located in the light exit direction of a corresponding laser.

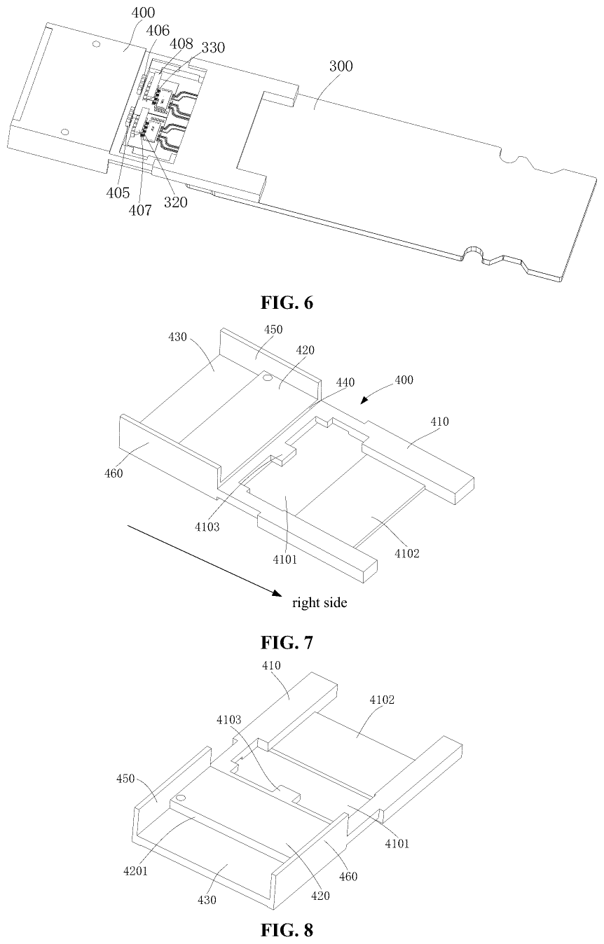

FIG. 7 is a structural diagram of the first support member in an optical module according to some embodiments of the present disclosure, and FIG. 8 is a structural diagram of the first support member in an optical module according to some embodiments of the present disclosure at another viewing angle. As shown in FIG. 7 and FIG. 8, in order to arrange a light emission component on the front surface of the first support member 400, the first support member 400 is configured to include a first support surface 410 and a second support surface 420, which are arranged along a left-right direction, with the second support surface 420 located at a left side of the first support surface 410. The circuit board 300 is disposed on the first support surface 410, such that the circuit board 300 is supported and fixed by the first support surface 410.

A front surface of the first support surface 410 is recessed relative to the second support surface 420, with a second connecting surface 440 provided between the first support surface 410 and the second support surface 420, and the front surface of the first support surface 410 is connected to the second support surface 420 via the second connecting surface 440. The back surface of the circuit board 300 is adhered to the front surface of the first support surface 410, such that the circuit board 300 is placed on the first support surface 410, and the front surface of the circuit board 300 is protruded relative to the second support surface 420.

In some embodiments, when the back surface of the circuit board 300 is adhered to the first support surface 410, the left side of the circuit board 300 abuts against the second connecting surface 440 such that the circuit board 300 is limited by the second connecting surface 440.

The first laser array 401 and the second laser array 403 are arranged side by side on the second support surface 420, and the first collimating lens array 402 and the second collimating lens array 404 are arranged side by side on the second support surface 420. The first collimating lens array 402 is located in the light exit direction of the first laser array 401, and the second collimating lens array 404 is located in the light exit direction of the second laser array 403.

In some embodiments, in order to transmit the emission lights generated by the first laser array 401 and the second laser array 403, the light emission component may also include a first optical fiber coupler and a second optical fiber coupler, and the first optical fiber coupler and the second optical fiber coupler are arranged side by side on the second support surface 420, wherein, the first optical fiber coupler is located in the light exit direction of the first laser array 401, and the second optical fiber coupler is located in the light exit direction of the second laser array 403.

The other ends of the first optical fiber coupler and the second optical fiber coupler are respectively connected to one end of an optical fiber ribbon, and the other end of the optical fiber ribbon is connected to the optical fiber adapter. In this way, the first optical fiber coupler couples an emission light transmitted from the first collimating lens array 402 to the optical fiber ribbon, and the second optical fiber coupler couples an emission light transmitted from the second collimating lens array 404 to the optical fiber ribbon, and then the emission lights are transmitted to the optical fiber adapter via the optical fiber ribbon, thereby realizing light emission.

In some embodiments, the first support member 400 may be a metal block fixedly connected to the lower shell 202 through screws, to ensure the stability of the first support member 400 such that the first support member 400 can stably support and fix the circuit board 300 and the light emission component.

When the first support member 400 is a metal block, heat generated by the first laser array 401 and the second laser array 403 during operation can be transmitted to the lower shell 202 through the metal block, thereby ensuring the heat dissipation efficiency of the laser.

The first support member 400 is provided therein with a through hole 4101. When the back surface of the circuit board 300 is placed on the first support surface 410, the through hole 4101 is located below the circuit board 300. Thus, an optoelectronic device may be arranged on the back surface of the circuit board 300 through the through hole 4101.

In some embodiments, the through hole 4101 of the first support member 400 is arranged in the first support surface 410, and a right side wall of the through hole 4101 is provided with an opening, which extends to a right side of the first support surface 410 (the right side along the arrow as shown in FIG. 7), such that the first support surface 410 is composed of a connecting arm and two support arms, and opposite ends of the connecting arm are respectively connected to the two support arms, and there is a gap between the two support arms.

In some embodiments, a connecting plate 4102 is disposed in the opening of the through hole 4101, and opposite sides of the connecting plate 4102 are connected to the two support arms to ensure a gap between the two support arms through the connecting plate 4102. A front surface of the connecting plate 4102 is recessed relative to the front surface of the first support surface 410, and a back surface of the connecting plate 4102 is flush with the back surface of the first support surface 410, such that, when the back surface of the circuit board 300 is adhered to the first support surface 410, there is a gap between the back surface of the circuit board 300 and the front surface of the connecting plate 4102, so as to facilitate arrangement of the reception optoelectronic chip and the signal wiring on the back surface of the circuit board 300. The signal wiring may pass through the gap between the front surface of the connecting plate 4102 and the back surface of the circuit board 300, thereby ensuring layout space of the optoelectronic chip on the circuit board 300.

The light reception component is directly arranged on the back surface of the circuit board 300 through the through hole 4101. External reception light transmitted from the optical fiber adapter is converged to the detector component on the back surface of the circuit board 300, such as the detector chip, and is converted into an electrical signal by the detector chip. The electrical signal is transmitted to the circuit board 300, thereby realizing light reception.

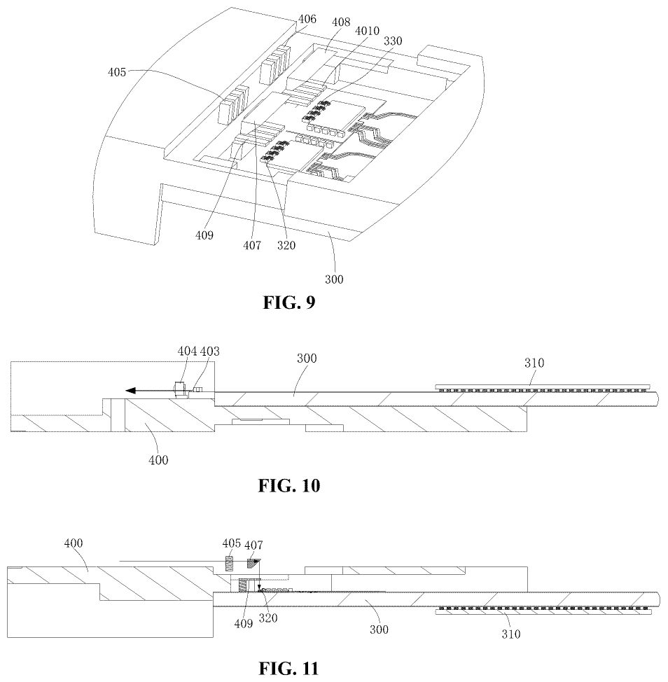

FIG. 9 is a partial perspective view of a circuit board, a first support member and a light reception component in an optical module according to some embodiments of the present disclosure, FIG. 10 is a partial perspective sectional view of a circuit board, a first support member and a light emission component in an optical module according to some embodiments of the present disclosure, and FIG. 11 is a partial perspective sectional view of a circuit board, a first support member and a light reception component in an optical module according to some embodiments of the present disclosure. As shown in FIG. 9 to FIG. 11, the light reception component includes a plurality of detector components, for example, the plurality of detector components include a first detector group 320 and a second detector group 330 arranged side by side on the back surface of the circuit board 300, and the first detector group 320 and the second detector group 330 are located in the through hole 4101.

Signal wirings are disposed on the back surface of the circuit board 300, and the first detector group 320 and the second detector group 330 are electrically connected to the signal wirings, respectively, such that electrical signals output from the first detector group 320 and the second detector group 330 are transmitted through the signal wirings.

Transimpedance amplifier may also be provided on the back surface of the circuit board 300, one end of which is electrically connected to the first detector group 320 and the second detector group 330, and the transimpedance amplifier is configured to amplify electrical signals output by the first detector group 320 and the second detector group 330; the other end of the transimpedance amplifier is electrically connected to the signal wirings to transmit the amplified electrical signal through the signal wirings.

The signal wirings arranged on the circuit board 300 may be connected to the DSP chip 310 (see FIG. 10). In this way, the amplified electrical signal output by the transimpedance amplifier is transmitted to the DSP chip 310 via the signal wiring. The electrical signal, after being processed by the DSP chip 310, is transmitted to the gold finger via the signal wiring on the front surface of the circuit board 300, and then transmitted to the host computer via the gold finger, thereby realizing light reception.

Since the first detector group 320 and the second detector group 330 are arranged on the back surface of the circuit board 300, and the back surface of the circuit board 300 is bonded and fixedly connected with the front surface of the first support surface 410, there is a height difference between the back surface of the first support member 400 and the back surface of the circuit board 300, resulting in the reception light transmitted from the optical fiber adapter cannot reach the first detector group 320 and the second detector group 330.

Since light reception directions of the first detector group 320 and the second detector group 330 are perpendicular to the circuit board 300, and the reception light transmitted by the optical fiber adapter is parallel to the circuit board 300, in order to inject the reception light into the first detector group 320 and the second detector group 330, the light reception component further includes a reflector including a first reflector 407 and a second reflector 408. Light incident surfaces of the first reflector 407 and the second reflector 408 are arranged opposite to the optical fiber adapter, a reflection surface of the first reflector 407 is located directly above the first detector group 320, and a reflection surface of the second reflector 408 is located directly above the second detector group 330, such that a part of the reception light is reflected to the first detector group 320 by the first reflector 407, and the remaining part of the reception light is reflected to the second detector group 330 by the second reflector 408.

In some embodiments, the reception light transmitted by the optical fiber adapter is divergent light. In order to ensure that the multi-path reception light is reflected to the first detector group 320 via the first reflector 407, the light reception component includes a collimating lens group, which includes a first collimating lens group 405. The first collimating lens group 405 is located between the optical fiber adapter and the first reflector 407. The first collimating lens group 405 converts the multi-path reception light into multi-path collimated light, which is reflected to the first detector group 320 via the first reflector 407.

In order to ensure that the multi-path divergent light is reflected to the second detector group 330 via the second reflector 408, the collimating lens group of the light reception component also includes a second collimating lens group 406. The second collimating lens group 406 is located between the optical fiber adapter and the second reflector 408. The second collimating lens group 406 converts the multi-path reception light into multi-path collimated light, which is reflected to the second detector group 330 via the second reflector 408.

In some embodiments, the light reception component further includes a first converging lens group 409 and a second converging lens group 4010. The first converging lens group 409 and the second converging lens group 4010 are fixed on the back surface of the circuit board 300 through a support block. The first converging lens group 409 is located between the first reflector 407 and the first detector group 320. The first converging lens group 409 is configured to converge the reception light reflected by the first reflector 407 into the first detector group 320. The second converging lens group 4010 is located between the second reflector 408 and the second detector group 330. The second converging lens group 4010 is configured to converge the reception light reflected by the second reflector 408 into the second detector group 330.

In some embodiments, since the first detector group 320 and the second detector group 330 are located in the through hole 4101, in order to achieve the reception of reception light, the collimating lens group and the reflector are both located in the through hole 4101, that is, the first collimating lens group 405, the second collimating lens group 406, the first reflector 407 and the second reflector 408 are also located in the through hole 4101.

In some embodiments, in order that the first collimating lens group 405, the second collimating lens group 406, the first reflector 407 and the second reflector 408 are located in the through hole 4101, the first collimating lens group 405 and the second collimating lens group 406 may be fixed on the first support surface 410 at a left edge of the through hole 4101, the first reflector 407 is fixed on the first collimating lens group 405, and the reflective surface of the first reflector 407 is located directly above the first detector group 320; the second reflector 408 is fixed on the second collimating lens group 406, and the reflective surface of the second reflector 408 is located directly above the second detector group 330.

As shown in FIGS. 10 and 11, the first laser array 401, the first collimating lens array 402, the second laser array 403 and the second collimating lens array 404 are arranged on the second support surface 420 of the first support member 400, and the DSP chip 310 on the front surface of the circuit board 300 is electrically connected to the first laser array 401 and the second laser array 403 through signal lines to drive the first laser array 401 and the second laser array 403 to generate multiple paths of optical signals of different wavelengths.

The optical fiber adapter may be disposed in the lower shell 202, and multiple paths of optical signals with different wavelengths may be transmitted to the optical fiber adapter through the optical fiber ribbon, and then transmitted through the optical fiber adapter, thereby realizing light emission.

The reception light transmitted from the optical fiber adapter is transmitted to the light reception component via the optical fiber ribbon, and the reception light is converted into collimated light via the first collimating lens group 405 and the second collimating lens group 406, and the collimated light is reflected by the first reflector 407 and the second reflector 408 as collimated light perpendicular to the back surface of the circuit board 300, and the reflected collimated light is respectively converged to the first detector group 320 and the second detector group 330 via the first converging lens group 409 and the second converging lens group 4010.

The first detector group 320 and the second detector group 330 convert the received optical signals into electrical signals, which are transmitted to the DSP chip 310 via the signal line. The DSP chip 310 processes the electrical signals and transmits them to the gold finger via the signal line, thereby achieving light reception.

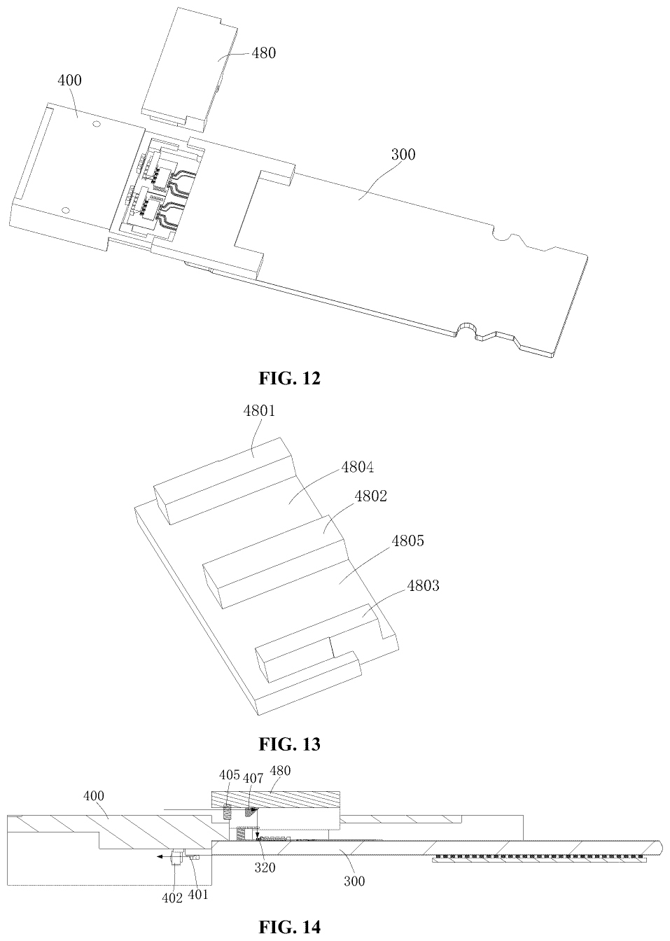

FIG. 12 is an exploded view of a circuit board, a first support, a light reception component and a cover plate in an optical module according to some embodiments of the present disclosure, FIG. 13 is a structural diagram of a cover plate in an optical module according to some embodiments of the present disclosure, and FIG. 14 is a partial perspective sectional view of a circuit board, a first support, a light emission component and a light reception component in an optical module according to some embodiments of the present disclosure. As shown in FIG. 12, FIG. 13 and FIG. 14, in order to fix the first collimating lens group 405, the second collimating lens group 406, the first reflector 407 and the second reflector 408, the optical module may include a cover plate 480 which is located between the back surface of the first support member 400 and the lower shell 202. The cover plate 480 is arranged opposite to the through hole 4101. The first collimating lens group 405, the second collimating lens group 406, the first reflector 407 and the second reflector 408 are all arranged on the cover plate 480, and the cover plate 480 covers the through hole 4101.

Referring to FIG. 13, the cover plate 480 may include a first support block 4801, a second support block 4803 and a third support block 4802. The first support block 4801, the second support block 4803 and the third support block 4802 extend from a front surface of the cover plate 480 towards the through hole 4101, and the third support block 4802 is located between the first support block 4801 and the second support block 4803. When the cover plate 480 is covered on the through hole 4101, the first support block 4801 and the second support block 4803 are respectively arranged on the back surface opposite to the first support surface 410, so as to support and fix the cover plate 480 through the first support member 400.

Referring back to FIG. 7 and FIG. 8, in some embodiments, a boss 4103 is provided in the through hole 4101, and the boss 4103 extends from the left side wall of the through hole 4101 towards the connecting plate 4102. The boss 4103 is provided corresponding to the third support block 4802 of the cover plate 480. When the cover plate 480 is covered on the through hole 4101, the first support block 4801 and the second support block 4803 are arranged on the back surface of the first support member 400, and the third support block 4802 is arranged on the boss 4103, such that the cover plate 480 is supported and fixed by the first support member 400 and the boss 4103, thereby ensuring the connection stability of the cover plate 480 and the first support member 400.

As shown in FIG. 13, the front surface of the cover plate 480 is separated into a first platform 4804 and a second platform 4805 by the first support block 4801, the second support block 4803 and the third support block 4802. The first platform 4804 is located between the first support block 4801 and the third support block 4802, and the second platform 4805 is located between the third support block 4802 and the second support block 4803.

In some embodiments, the first detector group 320 and the second detector group 330 are respectively arranged at opposite sides of the boss 4103, accordingly, the first collimating lens group 405 and the second collimating lens group 406 are respectively arranged at opposite sides of the boss 4103, and the first reflector 407 and the second reflector 408 are respectively arranged at opposite sides of the boss 4103. For example, the first collimating lens group 405 and the first reflector 407 are arranged on the first platform 4804 along a light reception direction, and the second collimating lens group 406 and the second reflector 408 are arranged on the second platform 4805 along a light reception direction, in such a way that the first collimating lens group 405, the first reflector 407, the second collimating lens group 406 and the second reflector 408 are placed in the through hole 4101 via the cover plate 480.

The first collimating lens group 405, the first reflector 407, the second collimating lens group 406 and the second reflector 408 are arranged on the cover plate 480, and then the assembled cover plate 480 is bonded to the back surface of the first support member 400 and the boss 4103, such that the cover plate 480 covers the through hole 4101 to ensure transmission optical path of the reception light.

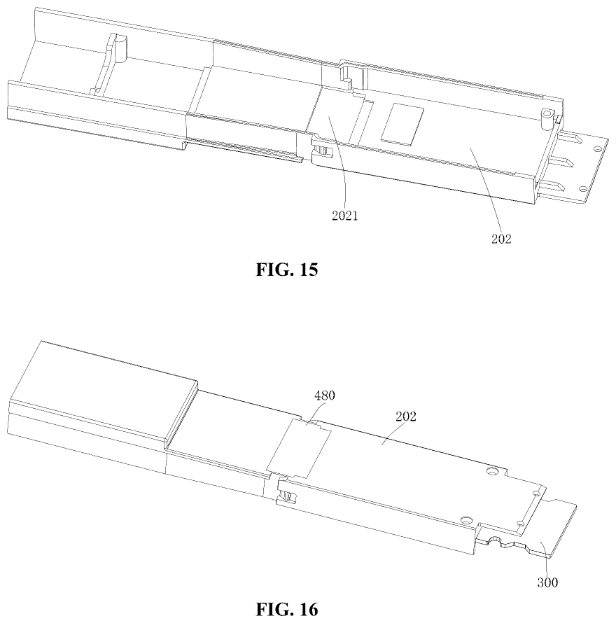

FIG. 15 is a structural diagram of a lower shell of an optical module provided according to some embodiments of the present disclosure, and FIG. 16 is a perspective diagram of a lower shell, a circuit board, a light emission component and a light reception component of an optical module provided according to some embodiments of the present disclosure. As shown in FIG. 15 and FIG. 16, when the cover plate 480 covers the through hole 4101, the back surface of the cover plate 480 is protruded relative to the back surface of the first support member 400, when the circuit board 300, the first support member 400, the light emission component, the light reception component and the cover plate 480 are placed in the cavity formed by the upper shell 201 and the lower shell 202, the protruded cover plate 480 results in a larger space in the cavity between the upper shell 201 and the lower shell 202.

In order to reduce the space of the cavity between the upper shell 201 and the lower shell 202, a through avoidance hole 2021 is provided in the back surface of the lower shell 202, and the avoidance hole 2021 is located corresponding to the through hole 4101 in the first support member 400. When the cover plate 480 is assembled, the cover plate 480 is embedded in the avoidance hole 2021, and the back surface of the cover plate 480 may be flush with the back surface of the lower shell 202.

In this way, the avoidance hole 2021 is configured to make way for the cover plate 480. When the circuit board 300, the first support member 400, the light emission component, the light reception component and the cover plate 480 are placed in the cavity formed by the upper shell 201 and the lower shell 202, a thickness of the cavity in an up-down direction may be slightly larger than a thickness formed by the circuit board 300, the first support member 400, the light emission component and the light reception component in the up-down direction, which can greatly reduce the overall thickness of the optical module.

With the first support member additionally provided to the optical module, the first support member supports and connects to the circuit board, the first support member and the circuit board form a carrier, on which the light emission component and the light reception component are directly placed, which can eliminate the BOX packaging structure of the light emission component and the light reception component, reduce the number of packaging structural parts, decrease invalid space in the optical module, and is helpful to the miniaturization and high-density integration development of the optical module.

In some embodiments, the light emission component and the light reception component are connected to multiple optical fiber adapters through an optical fiber ribbon, and one optical fiber of the optical fiber ribbon may transmit an optical signal of one wavelength. The provision of the optical fiber ribbon increases the cavity size in the optical module, so it is possible to multiplex the multiple paths of transmission lights from the light emission component and the multiple paths of reception lights received by the light reception component to reduce the number of optical fiber adapters.

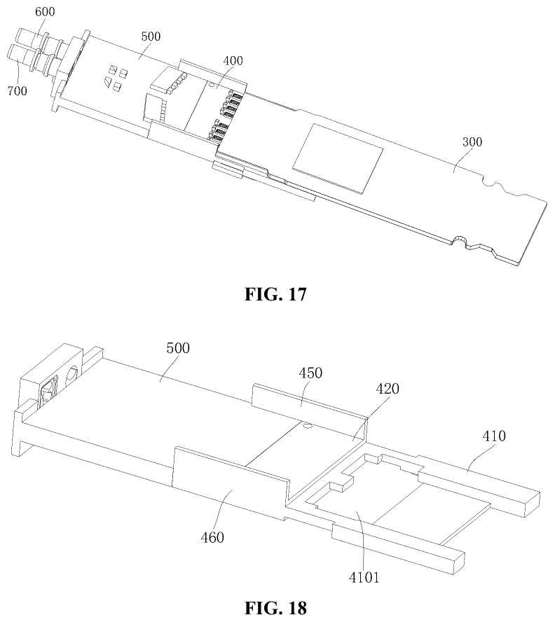

FIG. 17 is a perspective diagram of a circuit board, a first support member, a second support member, a light emission component and an optical fiber adapter of an optical module according to some embodiments of the present disclosure. As shown in FIG. 17, the optical module further includes a second support member 500, a first optical fiber adapter 600 and a second optical fiber adapter 700. One end of the first support member 400 supports and connects to the circuit board 300, and the other end of the first support member 400 is inserted into the second support member 500, such that the circuit board 300, the first support member 400 and the second support member 500 are connected and fixed.

The light emission components are directly disposed on the front surface of the first support member 400 and the front surface of the second support member 500, respectively, and the first optical fiber adapter 600 is inserted into the other end of the second support member 500, such that the light emission components and the first optical fiber adapter 600 are sequentially assembled on the front surfaces of the first support member 400 and the second support member 500 along the light emission direction. The laser component is electrically connected to the circuit board 300 to generate signal light according to the electrical signal transmitted by the circuit board 300. The signal light is converged to the first optical fiber adapter 600 through the light emission component on the first support member 400 and the second support member 500, thereby realizing light emission.

The light reception components are directly disposed on the back surfaces of the second support member 500 and the circuit board 300, respectively, and the second optical fiber adapter 700 is inserted into the other end of the second support member 500, such that the second optical fiber adapter 700 and the light reception components are sequentially assembled on the back surfaces of the second support member 500 and the circuit board 300 along the light reception direction. The reception light transmitted from the second optical fiber adapter 700 is transmitted to the back of the second support member 500, and after being processed by the light reception components on the back surface of the second support member 500, it is converged to the detector component on the back surface of the circuit board 300, and is converted into an electrical signal by the detector component, and the electrical signal is transmitted to the circuit board 300, thereby realizing the reception of light.

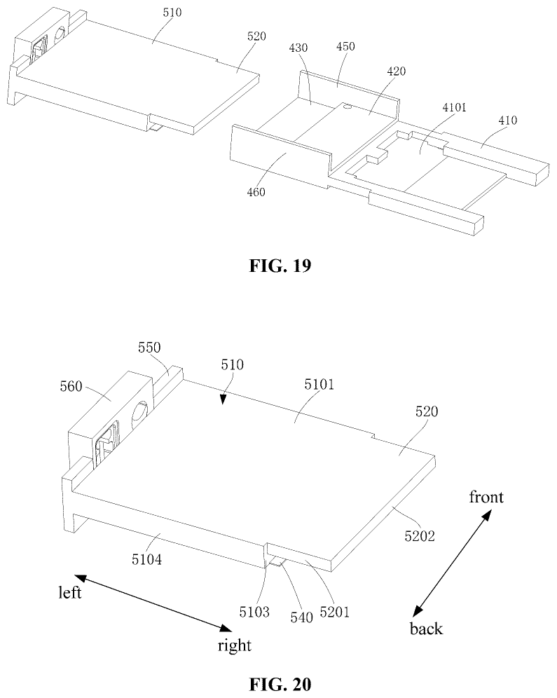

FIG. 18 is a perspective view of a first support member and a second support member of an optical module provided according to some embodiments of the present disclosure, and FIG. 19 is an exploded view of a first support member and a second support member of an optical module provided according to some embodiments of the present disclosure. As shown in FIG. 8, FIG. 18 and FIG. 19, in order to realize the connection and fixation between the first support member 400 and the second support member 500, the first support member 400 also includes a third support surface 430, the second support surface 420 is located between the third support surface 430 and the first support surface 410, the first support surface 410 supports and fixes the circuit board 300, and the third support surface 430 supports and fixes the second support member 500.

Referring to FIG. 8 and FIG. 19, the third support surface 430 is recessed relative to the second support surface 420, and the second support surface 420 is connected to the third support surface 430 via the first connecting surface 4201. The second support member 500 is disposed on the third support surface 430, and the front surface of the second support member 500 is flush with the second support surface 420.

Referring to FIG. 8 and FIG. 19, the first support member 400 further includes a first limiting plate 450 and a second limiting plate 460 arranged opposite to each other. The first limiting plate 450 is connected to one side of the second support surface 420 and one side of the third support surface 430, and the second limiting plate 460 is connected to the other side of the second support surface 420 and the other side of the third support surface 430. In this way, the first support member 400 is formed into a U-shaped plate composed of the second support surface 420, the third support surface 430, the first limiting plate 450 and the second limiting plate 460.

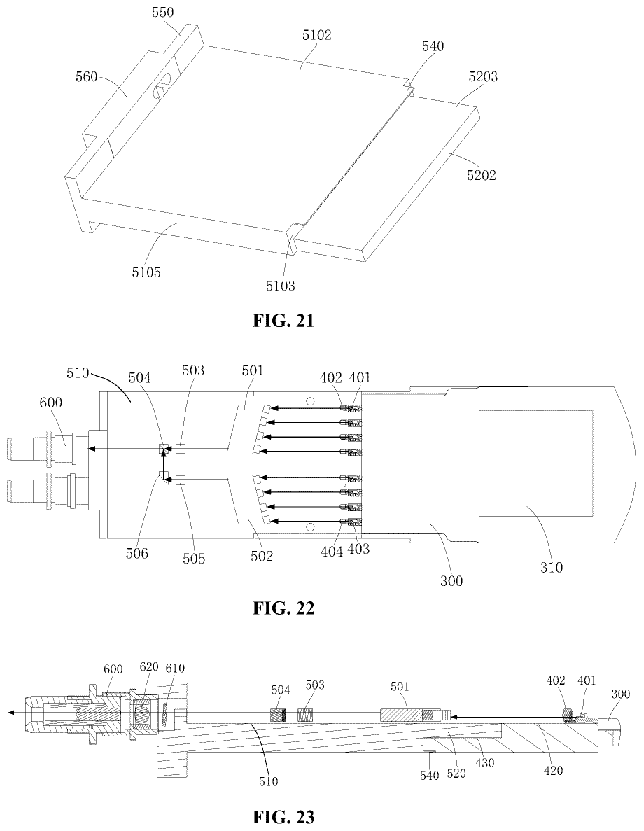

FIG. 20 is a structural diagram of the second support member of an optical module according to some embodiments of the present disclosure, and FIG. 21 is a structural diagram of the second support member of an optical module according to some embodiments of the present disclosure at another viewing angle. As shown in FIG. 20 and FIG. 21, the second support member 500 includes a main board 510, a first protrusion plate 520 and a second protrusion plate 540. The first protrusion plate 520 and the second protrusion plate 540 are both connected to one side of the main board 510, such that the first protrusion plate 520 and the second protrusion plate 540 extend from one side of the main board 510 towards the first support member 400. A front surface of the first protrusion plate 520 is flush with a front surface of the main board 510, and a back surface of the second protrusion plate 540 is flush with a back surface of the main board 510, and there is a gap between the back surface of the first protrusion plate 520 and the front surface of the second protrusion plate 540. One end of the first support member 400 is inserted into the gap between the first protrusion plate 520 and the second protrusion plate 540 to connect the first support member 400 with the second support member 500.

As shown in FIG. 20, in some embodiments, the main board 510 includes a front surface 5101, a back surface 5102, a first side 5103, a second side, a third side 5104 and a fourth side 5105. The first side 5103 faces the first support member 400, and the first side 5103 is arranged opposite to the second side. The third side 5104 is connected to the front surface 5101, the back surface 5102, the first side 5103 and the second side; and the third side 5104 is arranged opposite to the fourth side 5105. That is, the first side 5103 is the right side of the main board 510, the second side is the left side of the main board 510, the third side 5104 is the rear side of the main board 510, and the fourth side 5105 is the front side of the main board 510.

The first protrusion plate 520 and the second protrusion plate 540 extend from the first side 5103 towards the first support member 400, and a length of the first protrusion plate 520 in the left-right direction is greater than a length of the second protrusion plate 540 in the left-right direction, such that the back surface 5203 of the first protrusion plate 520 contacts the third support surface 430, and the front surface of the second protrusion plate 540 contacts the back surface of the first support member 400.

In some embodiments, the first protrusion plate 520 includes a first contact surface 5201, a second contact surface and a third contact surface 5202, wherein the third contact surface 5202 is arranged opposite to the first side 5103, the first contact surface 5201 is connected to the third contact surface 5202, the first side 5103, the front surface of the first protrusion plate 520 and the back surface 5203 of the first protrusion plate 520; and the first contact surface 5201 is arranged opposite to the second contact surface.

The first contact surface 5201 is recessed relative to the third side surface 5104, and the second contact surface is recessed relative to the fourth side surface 5105, such that a width of the first protrusion plate 520 in the front-to-back direction is smaller than a width of the main board 510 in the front-to-back direction.

When the first support member 400 is inserted between the first protrusion plate 520 and the second protrusion plate 540 of the second support member 500, the back surface of the first protrusion plate 520 is in contact and connected with the third support surface 430, the front surface of the second protrusion plate 540 is in contact and connected with the back surface of the first support member 400, the first contact surface 5201 of the first protrusion plate 520 abuts against the second limiting plate 460, the second contact surface abuts against the first limiting plate 450, the left side of the first support member 400 abuts against the first side 5103, and the third contact surface 5202 of the first protrusion plate 520 abuts against the first connecting surface 4201, thereby achieving the connection and fixation of the first support member 400 and the second support member 500.

FIG. 22 depicts a transmission optical path of an optical module provided according to some embodiments of the present disclosure, and FIG. 23 is a sectional view of the transmission optical path of an optical module provided according to some embodiments of the present disclosure. As shown in FIG. 22 and FIG. 23, the optical emission component also includes a first optical multiplexer 501, a second optical multiplexer 502 and a lens component. The first optical multiplexer 501 and the second optical multiplexer 502 are arranged side by side on the front surface of the second support member 500. The first optical multiplexer 501 is located in the light exit direction of the first laser array 401, and is configured to multiplex the 4-path collimated light output from the first collimating lens array 402 into a first composite light. The second optical multiplexer 502 is located in the light exit direction of the second laser array 403, and is configured to multiplex the 4-path collimated light output from the second collimating lens array 404 into a second composite light.

As shown in FIG. 22, the lens component includes a first lens 504 and a second lens 506 disposed on the front surface of the main board 510 of the second support member 500. The first lens 504 is disposed opposite to the first optical fiber adapter 600, and is located in the light exit direction of the first optical multiplexer 501. A first composite light output by the first optical multiplexer 501 directly passes through the first lens 504. The second lens 506 is located in the light exit direction of the second optical multiplexer 502. A second composite light output by the second optical multiplexer 502 is reflected at the second lens 506. The reflected second composite light is transmitted to the first lens 504, and is reflected again at the first lens 504. The re-reflected second composite light is combined with the first composite light passing through the first lens 504 to output one composite light.

In some embodiments, when the first composite light from the first optical multiplexer 501 is transmitted to the first lens 504, due to the change in the transmission medium, the first composite light is prone to be partially reflected at the light incident surface of the first lens 504 when it is transmitted to the first lens 504. The partially reflected first composite light may return to the first laser array 401 along the original path, affecting the light-emitting performance of the first laser array 401.

As shown in FIG. 22, in some embodiments, in order to prevent the reflected first composite light from affecting the light-emitting performance of the first laser array 401, a first isolator 503 is provided on the front surface of the main board 510. The first isolator 503 is located between the first lens 504 and the first optical multiplexer 501 and is configured to isolate part of the reflected light of the first composite light reflected at the first lens 504, so as to prevent the reflected light from returning to the first laser array 401 along the original path, thereby ensuring the light-emitting performance of the first laser array 401.

In some embodiments, a second isolator 505 is disposed on the front surface of the main board 510. The second isolator 505 is located between the second optical multiplexer 502 and the second lens 506, and is configured to isolate part of the reflected light of the second composite light reflected at the second lens 506 to prevent the reflected light from returning to the second laser array 403 along the original path, thereby ensuring the light-emitting performance of the second laser array 403.

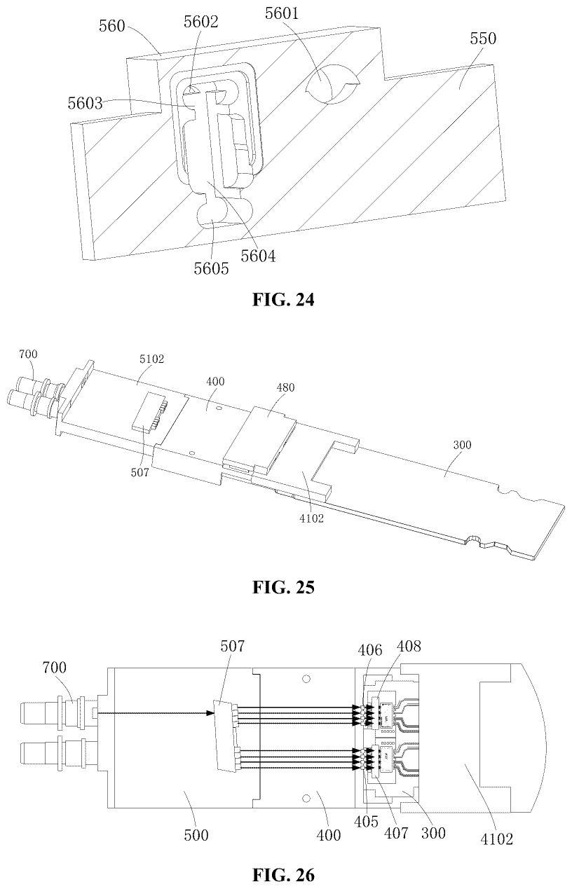

FIG. 24 is a sectional view of the second support member of an optical module provided according to some embodiments of the present disclosure. As shown in FIG. 24, a baffle 550 is provided on the second side of the main board 510, which protrudes relative to the front surface 5101 and the back surface 5102 of the main board 510 in the up-down direction; an assembly plate 560 is provided on the baffle 550, and the assembly plate 560 extends from an upper side surface of the baffle 550 towards the upper shell 201, and the assembly plate 560 is provided with a first light hole 5601 and a second light hole 5602, which are located above the front surface of the main board 510. The first optical fiber adapter 600 is connected to the second support member 500 through the first light hole 5601, and in this way, the first optical fiber adapter 600 and the second support member 500 are connected and fixed to each other through the first light hole 5601.

In some embodiments, the first lens 504 is arranged opposite to the first light hole 5601, an optical window 610 is arranged in the first light hole 5601, and a converging lens 620 is arranged in the first optical fiber adapter 600, such that the composite light output by the first lens 504 passes through the first light hole 5601 and the optical window 610 in sequence, and the transmitted composite light is converged and coupled to the first optical fiber adapter 600 through the converging lens 620, thereby realizing emission of multi-wavelength emission light of the same optical fiber.

The second optical fiber adapter 700 is connected to the second support member 500 through the second light hole 5602, such that the second optical fiber adapter 700 is located above the front surface of the second support member 500. The light reception component is disposed on the back surface of the second support member 500 and the back surface of the circuit board 300, and thus the reception light transmitted by the second optical fiber adapter 700 should be transmitted to the back surface of the second support member 500.

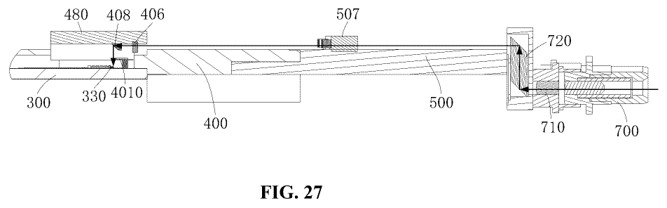

FIG. 25 is a perspective view of a circuit board, a first support member, a second support member, a light reception component and an optical fiber adapter of an optical module provided according to some embodiments of the present disclosure, FIG. 26 illustrates a reception optical path of an optical module provided according to some embodiments of the present disclosure, and FIG. 27 is a sectional view of the reception optical path of an optical module provided according to some embodiments of the present disclosure. Referring to FIG. 25 to FIG. 27, since the second optical fiber adapter 700 is located above the front surface of the second support member 500, in order to transmit the reception light transmitted by the second optical fiber adapter 700 from the front surface of the second support member 500 to the back surface of the second support member 500, a light-passing groove is provided on the assembly plate 560. The light-passing groove does not penetrate the assembly plate 560, and has an opening on the side of the light-passing groove facing the main board 510. A turning prism 720 is provided in the light-passing groove, and a light incident surface of the turning prism 720 corresponds to the second light hole 5602, and a light exiting surface of the turning prism 720 is located below the back surface of the main board 510, in such a way that the reception light transmitted by the second optical fiber adapter 700 is projected to the turning prism 720 through the second light hole 5602, and the turning prism 720 reflects the reception light twice, and the reception light which has been reflected twice is located below the back surface of the main board 510.

As shown in FIG. 24, in some embodiments, the light-passing groove includes a first light-passing groove 5603, a second light-passing groove 5604 and a third light-passing groove 5605, wherein the second light-passing groove 5604 is located between the first light-passing groove 5603 and the third light-passing groove 5605; the first light-passing groove 5603 is located above the front surface of the main board 510, and the first light-passing groove 5603 is communicated with the second light hole 5602; the third light-passing groove 5605 is located below the back surface of the main board 510, and is communicated with the first light-passing groove 5603 through the second light-passing groove 5604.

The light incident surface of the turning prism 720 is located in the first light-passing groove 5603, and the light exiting surface of the turning prism 720 is located in the third light-passing groove 5605. In this way, the reception light transmitted by the second optical fiber adapter 700 is incident on the light incident surface of the turning prism 720 through the second light hole 5602. The turning prism 720 reflects the reception light twice and then emits it from the light exiting surface. The emitted reception light is located below the back surface of the main board 510.

As shown in FIGS. 25, 26 and 27, the light reception component further includes an optical demultiplexer 507, which is arranged on the back surface of the main board 510. A light inlet of the optical demultiplexer 507 corresponds to the third light-passing groove 5605, such that the reception light emitted by the turning prism 720 is incident on the optical demultiplexer 507, and the optical demultiplexer 507 demultiplexes the one-path reception light into multiple paths of lights.

The second optical fiber adapter 700 is located above the front surface of the second support member 500 through the second light hole 5602. A collimating lens 710 is arranged in the second optical fiber adapter 700, and a turning prism 720 is arranged in the light-passing groove. A light incident surface of the turning prism is arranged opposite to the collimating lens 710, and a light exiting surface of the turning prism 720 is located below the back surface of the second support member 500. In this way, the reception light transmitted by the second optical fiber adapter 700 is converted into collimated light through the collimating lens 710, and the collimated light is reflected from the front surface of the second support member 500 to the back surface of the second support member 500 through the turning prism 720.

As shown in FIG. 26, the optical demultiplexer 507 is arranged on the back surface of the second support member 500; the first collimating lens group 405, the first reflector 407, the second collimating lens group 406, and the second reflector 408 are arranged on the cover plate 480; the cover plate 480 covers the through hole 4101 of the first support member 400; the first converging lens group 409 and the second converging lens group 4010 are fixed to the back surface of the circuit board 300 through the support block; and the first detector group 320 and the second detector group 330 are arranged on the back surface of the circuit board 300.

Referring to FIG. 27, in some embodiments, the reception light transmitted from the second optical fiber adapter 700 is converted into collimated light by the collimating lens 710; the collimated light is reflected by the turning prism 720 and then incident on the optical demultiplexer 507; the optical demultiplexer 507 demultiplexes the one path reception light into multiple paths of lights, and the multiple paths of lights are respectively converted into multiple collimated lights by the first collimating lens group 405 and the second collimating lens group 406; and the multiple collimated lights are reflected by the first reflector 407 and the second reflector 408 as multiple reflected lights perpendicular to the back surface of the circuit board 300, and the multiple reflected lights are converged to the first detector group 320 and the second detector group 330 by the first converging lens group 409 and the second converging lens group 4010; and the first detector group 320 and the second detector group 330 convert the multiple lights into electrical signals.

In some embodiments, the electrical signals output by the first detector group 320 and the second detector group 330 are amplified by a transimpedance amplifier, and the amplified electrical signals are transmitted to the DSP chip 310 via signal wiring arranged on the back surface of the circuit board 300. The DSP chip 310 processes the electrical signals, the processed electrical signals are then transmitted to the host computer via the gold finger, thereby realizing light reception.

In some embodiments, since the first support member 400 is a metal block, the second support member 500 may also be a metal block so as to ensure the connection stability among the first support member 400, the second support member 500, the first fiber optic adapter 600 and the second fiber optic adapter 700.

An optical module provided according to some embodiments of the present disclosure may include a circuit board, a first support member, a second support member, a first optical fiber adapter, a second optical fiber adapter, a light emission component and a light reception component. One end of the first support member is connected to the circuit board, such that the first support member is connected to the circuit board. The other end of the first support member is inserted into one end of the second support member, such that the first support member is fixedly connected to the second support member. The first optical fiber adapter is inserted into the other end of the second support member, and the first optical fiber adapter is configured to emit signal light, that is, light emitted by the light emission component is transmitted through the first optical fiber adapter. The second optical fiber adapter is inserted into the other end of the second support member, and the second optical fiber adapter is configured to transmit reception light, that is, an external reception light is transmitted to the second support member through the second optical fiber adapter. The light emission component includes a laser component, an optical multiplexer and a lens component. The laser component is arranged on the front surface of the first support member and is electrically connected to the circuit board; the laser component is configured to generate emission light. The optical multiplexer and the lens component are arranged on the front surface of the second support member, wherein the optical multiplexer is configured to multiplex multiple paths of emission light generated by the laser component into one path of composite light, and the lens component is configured to reflect and converge the composite light to the first optical fiber adapter. In this way, the light emission component is directly placed on the first support member and the second support member, and thus BOX packaging structure of the light emission component may be omitted. The light reception component includes a turning prism, an optical demultiplexer, a reflector and a detector component. The turning prism is arranged on the second support member, and the turning prism is configured to reflect the reception light transmitted from the second optical fiber adapter from the front surface of the second support member to the back surface so as to change the transmission direction of the reception light. The optical demultiplexer is arranged on the back surface of the second support member, and the optical demultiplexer is configured to demultiplex the reflected reception light into multiple paths of lights. A through hole is provided in the first support member, and the reflector is located in the through hole. The detector component is arranged on the back surface of the circuit board, and the multiple paths of lights are reflected to the detector component by the reflector, thereby achieving light reception. In this way, the light reception component is placed on the first support member, the second support member and the circuit board, and thus BOX packaging structure of the light reception component can be omitted.

In some embodiments of the present disclosure, a first support member and a second support member are provided to the optical module, wherein the first support member supports and connects to the circuit board, and the second support member is fixedly connected to the first support member. The first support member, the second support member and the circuit board form a carrier, on which the light emission component and the light reception component are directly placed, which can save the BOX packaging structure of the light emission component and the light reception component, reduce the number of packaging structural parts, decrease invalid space in the optical module, and is conducive to the miniaturization and high-density integration development of the optical module.

Finally, it should be noted that the above embodiments are only used to illustrate the technical solutions of the present disclosure, rather than to limit them. Although the present disclosure has been described in detail with reference to the aforementioned embodiments, those skilled in the art should understand that modifications may be made to the technical solutions of the aforementioned embodiments, or equivalent replacements may be made to some of the technical features of them. However, these modifications or replacements do not deviate the essence of the corresponding technical solutions from the spirit and scope of the technical solutions of the embodiments of the present disclosure.

What is claimed is:

1. An optical module, comprising:
an upper shell;
a lower shell configured to combine with the upper shell to form a package cavity;
a circuit board arranged in the package cavity, wherein one end of a front surface of the circuit board is disposed with a gold finger, and the other end of the front surface is disposed with a welding pin, and the gold finger is electrically connected to the welding pin through a signal line arranged on the front surface; and a signal wiring is arranged on a back surface of the circuit board;
a first support member disposed in the package cavity, wherein one end of the first support member supports and fixes the circuit board, and a through hole is formed in the first support member, the through hole being located below the circuit board; the welding pin is located above the first support member, and the gold finger is located outside the first support member;
a laser component disposed on a front surface of the first support member, the laser component being electrically connected to the welding pin through wire bonding and being configured to generate an emission light;
a cover plate disposed in the package cavity, the cover plate being supported and connected to a back surface of the first support member and embedded in the through hole;
a detector component disposed on the back surface of the circuit board, the detector component being located in the through hole, electrically connected to the signal wiring and configured to convert a reception light into an electrical signal, and the electrical signal is transmitted through the signal wiring; and
a reflector disposed on the cover plate, the reflector being configured to reflect the reception light to the detector component.

2. The optical module according to claim 1, wherein the first support member comprises a first support surface and a second support surface, the first support surface being recessed relative to the second support surface; the through hole is arranged in the first support surface; the first support surface supports and fixes the circuit board; and the laser component is arranged on the second support surface.

3. The optical module according to claim 2, wherein the front surface of the circuit board is protruded relative to the second support surface; and a wire bonding height of the laser component is flush with the front surface of the circuit board.

4. The optical module according to claim 3, wherein a second connecting surface is provided between the first support surface and the second support surface; the first support surface is connected to the second support surface through the second connecting surface; and one end of the circuit board abuts against the second connecting surface.

5. The optical module according to claim 4, wherein an opening is provided at one side of the through hole facing away from the second support surface, a connecting plate is provided in the opening, and the connecting plate is connected to two side walls of the opening;
a front surface of the connecting plate is recessed relative to the first support surface such that a gap is formed between the back surface of the circuit board and the front surface of the connecting plate when the back surface of the circuit board is supported on the first support surface; and the signal wiring passes through the gap; and a back surface of the connecting plate is flush with the back surface of the first support member.

6. The optical module according to claim 5, further comprising a collimating lens group, wherein the collimating lens group and the reflector are both arranged on a support surface of the cover plate; the collimating lens group is configured to convert a reception light transmitted from a back of the first support member into a collimated light, and the reflector is configured to reflect the collimated light to the detector component.

7. The optical module according to claim 6, wherein the cover plate comprises a first support block and a second support block arranged on the back surface of the first support member, and the cover plate covers the through hole.

8. The optical module according to claim 7, wherein a boss is arranged in the through hole, the boss extending from a side wall of the through hole close to the second connecting surface towards the connecting plate;
the optical module comprising a plurality of detector components, the plurality of the detector components comprising a first detector group and a second detector group which are arranged at opposite sides of the boss, respectively; and
the cover plate further comprises a third support block located between the first support block and the second support block, and the boss supports and connects the third support block.

9. The optical module according to claim 1, wherein a through avoidance hole is provided in a back surface of the lower shell, and the cover plate is embedded in the avoidance hole.

10. The optical module according to claim 1, wherein:
the laser component is a laser component array, and the front surface of the circuit board is disposed with a high-speed transmission signal line array;
the detector component is a reception optoelectronic chip array, and the back surface of the circuit board is disposed with a high-speed reception signal line array; and
the welding pin is a welding pin array, which is connected to the high-speed transmission signal line array, but is not connected to the high-speed reception signal line array.

11. The optical module according to claim 10, wherein a digital signal processing chip is arranged on the front surface of the circuit board, the digital signal processing chip being connected to the high-speed transmission signal line array on the front surface of the circuit board, and being connected to the high-speed reception signal line array on the back surface of the circuit board through a via hole.

12. An optical module, comprising:
a circuit board, wherein one end of a front surface of the circuit board is disposed with a gold finger, the other end of the front surface is disposed with a welding pin, and the gold finger is electrically connected to the welding pin through a signal line arranged on the front surface; and a signal wiring is arranged on a back surface of the circuit board;
a first support member, one end of which supports and fixes the circuit board, the first support member is provided with a through hole, and the through hole is located below the circuit board; the welding pin is located above the first support member, and the gold finger is located outside the first support member;
a laser component disposed on a front surface of the first support member and is electrically connected to the welding pin through wire bonding; the laser component is configured to generate an emission light;
a detector component disposed on the back surface of the circuit board, is located in the through hole, and is electrically connected to the signal wiring; the detector component is configured to perform photoelectric conversion on a reception light;
a second support member, one end of which is connected to the other end of the first support member;
a first optical fiber adapter inserted into the other end of the second support member and configured to emit a signal light; and
a second optical fiber adapter inserted into the other end of the second support member and configured to transmit a reception light.

13. The optical module according to claim 12, wherein the first support member comprises a first support surface, a second support surface and a third support surface, wherein the first support surface is recessed relative to the second support surface, and the second support surface is located between the third support surface and the first support surface; and the third support surface is recessed relative to the second support surface;
the through hole is arranged in the first support surface, and the first support surface supports and fixes the circuit board;
a first connecting surface is provided between the second support surface and the third support surface, and the third support surface is connected to the second support surface through the first connecting surface; and
the second support member is arranged on the third support surface, and a front surface of the second support member is flush with the second support surface.

14. The optical module according to claim 13, wherein the first support member further comprises a first limiting plate and a second limiting plate which are arranged opposite to each other, wherein the first limiting plate is connected to one sides of the second support surface and the third support surface, and the second limiting plate is connected to the other sides of the second support surface and the third support surface; and the welding pin is located between the first limiting plate and the second limiting plate; and
opposite side surfaces of the second support member abut against the first limiting plate and the second limiting plate.

15. The optical module according to claim 13, wherein the second support member comprises a main board, a first protrusion plate and a second protrusion plate, wherein the first protrusion plate and the second protrusion plate are both connected to one side of the main board, a front surface of the first protrusion plate is flush with a front surface of the main board, a back surface of the second protrusion plate is flush with a back surface of the main board, and there is a gap between the first protrusion plate and the second protrusion plate;
one end of the first support member is inserted between the first protrusion plate and the second protrusion plate, and a back surface of the first protrusion plate is in contact with and connected to the third support surface.

16. The optical module according to claim 15, wherein the main board comprises a first side surface, a second side surface, a third side surface and a fourth side surface, wherein the first side surface faces the first support member and is arranged opposite to the second side surface; the third side surface is connected to the first side surface, the second side surface, the front surface of the main board and the back surface of the main board; and the third side surface is arranged opposite to the fourth side surface;
the first protrusion plate comprises a first contact surface, a second contact surface and a third contact surface, wherein the first contact surface is arranged opposite to the second contact surface, and the third contact surface is arranged opposite to the first side surface; the first contact surface and the second contact surface abut against the first limiting plate and the second limiting plate; and the third contact surface abuts against the first connecting surface.

17. The optical module according to claim 16, wherein a baffle is provided on the second side surface, and the baffle is protruded relative to the front surface and back surface of the main board; an assembly plate is provided on the baffle plate, and the assembly plate is provided therein with a first light hole and a second light hole, the first light hole and the second light hole being located above the front surface of the main board; the first optical fiber adapter is connected to the second support member through the first light hole, and the second optical fiber adapter is connected to the second support member through the second light hole;
the assembly plate is further provided with a light-passing groove which does not pass through the assembly plate, and the light-passing groove has an opening at one side of the light-passing groove facing the main board; the light-passing groove extends from the front surface of the main board to the back surface of the main board, and is communicated with the second light hole; a turning prism is arranged in the light-passing groove, and the turning prism is configured to reflect a reception light transmitted by the second optical fiber adapter from a front surface of the second support member to a back surface of the second support member.

18. The optical module according to claim 17, wherein the light-passing groove comprises a first light-passing groove, a second light-passing groove and a third light-passing groove, wherein the second light-passing groove is located between the first light-passing groove and the third light-passing groove; the first light-passing groove is located above the front surface of the main board, and is communicated with the second light hole; the third light-passing groove is located below the back surface of the main board, and the third light-passing groove is communicated to the first light-passing groove through the second light-passing groove; and
a light incident surface of the turning prism is located in the first light-passing groove, and a light exiting surface of the turning prism is located in the third light-passing groove.

19. The optical module according to claim 17, further comprising:
a collimating lens disposed in the second optical fiber adapter and is arranged opposite to a light incident surface of the turning prism, wherein the collimating lens is configured to convert the reception light transmitted by the second optical fiber adapter into a collimated light, and the turning prism is configured to reflect the reception light in form of the collimated light from the front surface of the second support member to the back surface of the second support member; and
an optical demultiplexer arranged on the back surface of the main board, wherein a light inlet of the optical demultiplexer corresponds to the light-passing groove, and the optical demultiplexer is configured to demultiplex the reception light transmitted by the turning prism into multiple paths of lights.

20. The optical module according to claim 12, further comprising:
a lens component disposed on the front surface of the second support member, the lens component being configured to reflect and converge the emission light to the first optical fiber adapter, and
a reflector located in the through hole, the reflector being configured to reflect the reception light transmitted from the second optical fiber adapter.
